(19) United States
(12) Patent Application Publication
(10) Pub. No.: US 2015/0043749 A1
(43) Pub. Date: Feb. 12, 2015

(54) Recursive Audio Modulation System Using Nested Inductor Arrays

(71) Applicant: James J. McGourty, JR., Denville, NJ (US)

(72) Inventor: James J. McGourty, JR., Denville, NJ (US)

(21) Appl. No.: 14/524,523

(22) Filed: Oct. 27, 2014

Related U.S. Application Data
(63) Continuation-in-part of application No. 13/373,014, filed on Nov. 2, 2011, now abandoned.

(51) Int. Cl. H03G 5/24

(52) U.S. Cl. CPC H03G 5/24
USPC 381/102

(57) ABSTRACT

Nested inductor arrays magnetically modulate an analog audio input signal recursively, so that the overall amplitude envelope of the output signal replicates the wave pattern of the input signal. The nested inductor arrays produce multiple levels of recursive modulation, so that the output signal incorporates multiple integrated self-similar harmonic layers. The phasing of the various layers are locked in by the analog waveform of the output signal itself. As a result, the spatial “depth” and temporal “immediacy” of the original analog recording is restored and can be encoded in digital format.

### REFERENCE TO RELATED APPLICATION

The present application is a Continuation-in-Part of U.S. patent application Ser. No. 13/373,104, filed on Nov. 4, 2011.

### BACKGROUND OF THE INVENTION

The present invention relates to the field of audio processors and amplifiers, and more particularly to the field of magnetic audio processors and amplifiers.

Since the dawn of the digital audio era, there has been a been a perception among a substantial sector of the audiophile community that something is lost in translating music from analog to digital format. The difference in sound quality in going from analog to digital has been variously, and somewhat subjectively, described as loss of “brightness”, “warmth” and even “emotional impact”.

Viewed more objectively, the limitation of digital sound quality can be attributed to the inherent loss of resolution that goes with converting from a continuous analog signal, with its theoretically infinite resolution capacity, to a “quantized” or “digitized” format, consisting of non-continuous bits of the sampled signal. This may be described as a loss of a “spatial” quality or “depth”—as if the digital conversion “flattens” one or more of the audio dimensions of the analog signal.

Another aspect of the “dimensional” difference between analog and digital audio relates to time. In an analog signal, the time dimension is, so to speak, “built in” to the waveform, but the same is not true in the digital format, in which the quantized bits of information must be sequenced and timed by a separate “digital clock”. Consequently, digital audio has an inherent “phasing” problem, which becomes particularly troublesome when trying to merge different “layers” of sound so as to recreate musical depth and richness. This problem manifests itself in digital “jitter”, where different layers of the sound fall out of phase. This “out of sync” problem does not exist for an analog signal, which has the capacity to incorporate virtually limitless levels of detail and harmonics within a waveform which functions as its own “clock”. Because the time dimension is integrated into the analog signal itself, analog sound reproduction has a quality of immediacy that is difficult to replicate in the digital format.

On the other hand, there are many advantages to the digital format, not the least of which are noise reduction and reproducibility. Therefore, it would be very advantageous to retain the advantages of digital recordings while restoring some of the lost “depth” and “immediacy” of analog recordings. The present invention uses a series of nested inductor arrays to process a digitized audio signal recursively so as to restore lost “spatial” sound resolution and reintegrate timing so as to recapture the immediacy of the analog recording. The fundamental innovation which makes this possible is known as “fractal interpolation”, which works on the principle of “self-similarity”. “Self-similarity” means that the structure of the parts resembles the overall structure of the whole, as is the case in fractal geometry. The principle of “self-similarity” is in widespread use in enhancing the resolution of digital photographs and video recordings.

Attempts to apply fractal interpolation to the enhancement of digital audio signals have thus far been limited to digital signal processing to add harmonics using non-linear transfer functions. Examples of this technique are described in the U.S. patents to Massie (U.S. Pat. No. 5,748,747) and Curtin (U.S. Pat. No. 6,208,969). But these techniques can only generate one or more digitized harmonic overlays, which are not re-integrated with the original audio waveform and are, therefore, difficult to synchronize with the primary signal.

The present invention, on the other hand, uses digital audio files that have been converted to analog format, and then processes the analog signal recursively through multiple nested levels of inductors, using a methodology that shares certain characteristics with magnetic amplifiers. Magnetic amplifiers are essentially transformers with a third “control” coil added to the conventional primary and secondary coils. In the absence of a biasing signal in the control coil, most of the magnetic flux generated by the varying current in the primary coil will be coupled into the control/input coil, which offers a lower magnetic reluctance path than the secondary/output coil. Therefore, in the unbiased condition, the output voltage developed across the secondary/output coil will be minimal. As the biasing signal increases in the control/input coil, it becomes increasingly saturated and its magnetic reluctance increases, causing more of the magnetic flux from the primary coil to couple into the secondary/output coils, thereby inducing a greater output voltage. The output from the secondary coils thus constitutes an amplified version of the input into the control coil. In a true magnetic amplifier, the signal input to the control coil magnetically modulates the output signal from the secondary coil, in a manner analogous to the way the signal applied to the grid of a triode vacuum tube or the base of a transistor electrically modulates the output signal from the plate or collector.

As described in the patent literature, magnetic amplifiers have typically been designed to operate as switching and control circuits, using the magnetic saturation characteristics of transformers. The emphasis in such transformer-based amplifier circuits is on high gain, in which a modest input signal can control much larger electrical loads. While the rapid response time enabled by such “mag-amps” is a factor in such switching/control circuits, high modulation fidelity between input and output signals is not a consideration. Consequently, this class of magnetic amplifier cannot be adapted for high quality audio amplification. Examples of this type of magnetic amplifier circuit are the power supply taught by the patent of Peterson (U.S. Pat. No. 4,916,590) and the switching regulator circuit taught by the patent of Washburn, et al. (U.S. Pat. No. 4,841,428).

While the patent of Carver (U.S. Pat. No. 4,218,660) claims to teach a magnetic audio amplifier, the Carver circuit is actually a power-supply control circuit rather than a true signal amplifier. It uses the amplitude of an input audio signal to control the amplifier's power supply, so that more power is supplied when the audio amplitude increases. But the Carver device does not generate a magnetically modulated output signal, as would a true audio mag-amp.

The patent of Jeong (U.S. Pat. No. 6,867,646) describes a demodulation apparatus for a digital audio amplifier. While this patent teaches the use of paired inductors to improve signal-to-noise ratio, it does not utilize magnetic audio signal modulation. Similarly, the patent application of Oxford et al. (US2007/0248233 A1) uses a biased inductor to dynamically adjust the spectral content of an audio signal to produce harmonic consonance, but it does not teach a magnetic audio modulation or amplification system.

While the present invention can be used for signal amplification, depending on the constituents used in the first stage inductors, its primary objective and effect is to magnetically modulate an audio input signal recursively, so that the overall amplitude envelope of the output signal replicates the wave pattern of the input signal. The nested inductor arrays of the present invention produce multiple levels of recursive modulation, so that the output signal incorporates multiple integrated self-similar harmonic layers, such that the phasing of the various layers are locked in by the analog waveform of the output signal itself. As a result, the spatial “depth” and temporal “immediacy” of the original analog recording is restored and can now be encoded in digital format.

### SUMMARY OF THE INVENTION

As an aid in understanding the difference between the present invention and the prior art methods of audio signal processing, we refer to FIGS. 1A and 1B, which illustrate the linear amplification (output proportional to input) of a sinusoidal input signal of constant amplitude. In the same vein, FIGS. 2A and 2B illustrate the linear amplification of a saw-tooth input signal of constant amplitude. In both cases it is noted that the envelopes of the output signal, appearing as dotted lines in FIGS. 1B and 2B, bear no spatial similarity to the waveforms of the output signal. Nor do output signal envelopes have any definite temporal relationship to the output signal waves, which can be displaced within the envelope without affecting the signal pattern.

When modulated recursively, however, the same input signals shown in FIGS. 1A and 2A produce the output signals depicted in FIGS. 3A and 3B, respectively. In both cases, there is self-similarity between the overall waveform of the amplitude envelopes (appearing as the dark lines) and the output signals, so that there is an integral “fit” of the signal within the envelope that fixes both their spatial and temporal relationship. Moreover, since the recursively modulated output waves must fit within their self-similar envelope, there is an automatic harmonic relationship between the overall amplitude envelope and the output signal. In the examples given in FIGS. 3A and 3B, the modulated output signals are the third harmonics of the envelope waveform, but we could just as well have chosen the second, fourth, fifth or higher harmonics to illustrate this point. For each of the harmonics, the unifying principle of the recursive modulation is that the combination of the individual wave patterns replicates the wave pattern of the envelope, such that the amplitudes of the harmonic components vary in way that adheres to the outline of the overall amplitude envelope.

The multiple levels of nested inductor arrays utilized in the present invention also produce multiple levels of self-similarity in the output signal waveform. As exemplified in FIGS. 4A and 4B, a second-order recursive modulation of sample sinusoidal and saw tooth input signals produces yet higher harmonics which fit within the waveforms of the first-order recursive modulation (shown as dotted lines). In effect, the first-order output signals (dotted lines) serve as “envelopes” for the second-order modulated signals (lighter solid lines), so that higher order recursive modulation yields an output signal structure of “envelopes within envelopes”, which ultimately approaches a fractal geometry of “envelopes within envelopes within envelopes . . . ”.

It should also be noted that higher order recursive modulation automatically integrates higher harmonics into the complex output signal structure. Thus, in the example given in FIG. 4A, the second-order modulated sinusoidal signal (lighter solid line) is the fourth harmonic of the first-order signal (dotted line) and the twelfth harmonic of the overall amplitude envelope (darker solid line). Similarly, in the saw tooth instance depicted in FIG. 4B, the second-order modulated signal (lighter solid line) is the second harmonic of the first-order signal (dotted line) and the sixth harmonic of the overall amplitude envelope (darker solid line). What is especially noteworthy is that the recursive modulation process generates all of the higher order harmonics spontaneously and synchronously with the overall output signal, thereby avoiding the complications of patch-work non-linear digital signal processing and its attendant phasing problems.

Using the principle of fractal interpolation, therefore, the present invention restores harmonic content without the timing/synchronization issues of digital processing, so that the depth and immediacy of the original analog recording is recaptured.

The foregoing summarizes the general design features of the present invention. In the following sections, specific embodiments of the present invention will be described in some detail. These specific embodiments are intended to demonstrate the feasibility of implementing the present invention in accordance with the general design features discussed above. Therefore, the detailed descriptions of these embodiments are offered for illustrative and exemplary purposes only, and they are not intended to limit the scope either of the foregoing summary description or of the claims which follow.

### BRIEF DESCRIPTION OF THE DRAWINGS

FIGS. 1A and 1B illustrate linear ampliflication of an exemplary sinusoidal input signal in accordance with the prior art, with FIG. 1A depicting the input signal, FIG. 1B depicting the amplified signal, and the signal envelopes shown by dotted lines;

FIGS. 2A and 2B illustrate linear amplification of an exemplary saw-tooth input signal in accordance with the prior art, with FIG. 2A depicting the input signal, FIG. 2B depicting the amplified signal, and the signal envelopes shown by dotted lines;

FIGS. 3A and 3B illustrate a first-order recursive amplification of the exemplary sinusoidal input signal depicted in FIG. 1A and the exemplary saw-tooth input signal depicted in FIG. 2A, respectively, with the overall signal envelopes shown as the darker lines;

FIGS. 4A and 4B illustrate a second-order recursive amplification of the exemplary sinusoidal input signal depicted in FIG. 1A and the exemplary saw-tooth input signal depicted in FIG. 2A, respectively, with the overall signal envelopes shown as the darker lines and the first-order signal envelopes shown as the dotted lines;

FIG. 5A is a side perspective view of the control inductor array of the preferred embodiment of the present invention;

FIG. 5B is a side perspective view of the processing inductor array of the preferred embodiment of the present invention;

FIG. 6 is a cross-section view of the processing inductor array through the line A-A′ shown in FIG. 5B; and

FIG. 7 is a schematic circuit diagram of the three stages of nested inductor arrays of an exemplary embodiment of the present invention.

### DETAILED DESCRIPTION OF THE PREFERRED EMBODIMENT

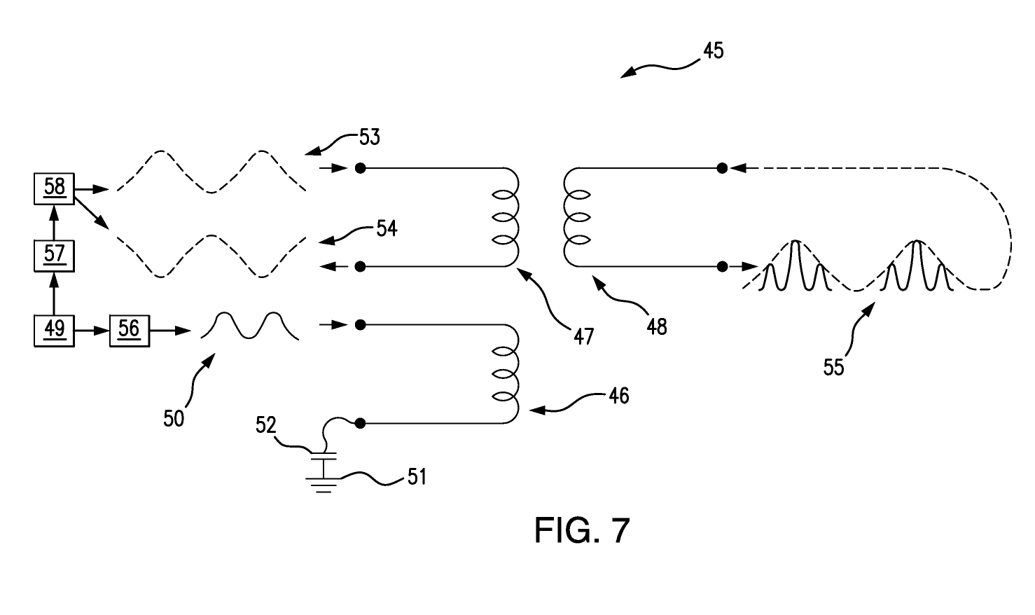

As illustrated schematically in FIG. 7, an exemplary recursive modulation process according to the present invention is achieved using three levels or stages of nested inductor arrays 45. Each inductor stage is “nested” in the sense of being located within the next higher stage, so that the inductor coils of Stage 1 46 are located inside the cores of the Stage 2 inductor coils 47, which are located within the cores of the Stage 3 48 inductor coils. (While a three-stage nested array is illustrated in this example, it is to be understood that additional nested stages can be added; for instance, Stage 4 inductor coils can encompass Stages 1-3, etc.) While each of the inductor stages on its own has only an air core, the lower stages nested within that air gap function to change the overall magnetic permeability of the core, so that each progressively lower stage of inductors acts as a “core element” of the higher stages.

The innermost Stage 1 level of inductor coils 46 is the first-order modulation stage, which receives the digital input audio signal 49 converted by a first-stage digital-to-analog signal processor 56 to analog format 50. The Stage 1 inductors 46 have air cores and their windings comprise wires or strips of a paramagnetic conductor, such as aluminum, combined with or alternating with wires or strips of a ferromagnetic conductor, such as nickel. The flow of the input signal 50 through the Stage 1 inductor 46 is single-ended, uni-directional, “push” phase only, going to ground 51 through a capacitor 52. The function of the Stage 1 inductors 46 is partly analogous to that of the “control leg” of a magnetic amplifier, but they also function as part of the cores of the inductors of Stages 2 through 3 47-48.

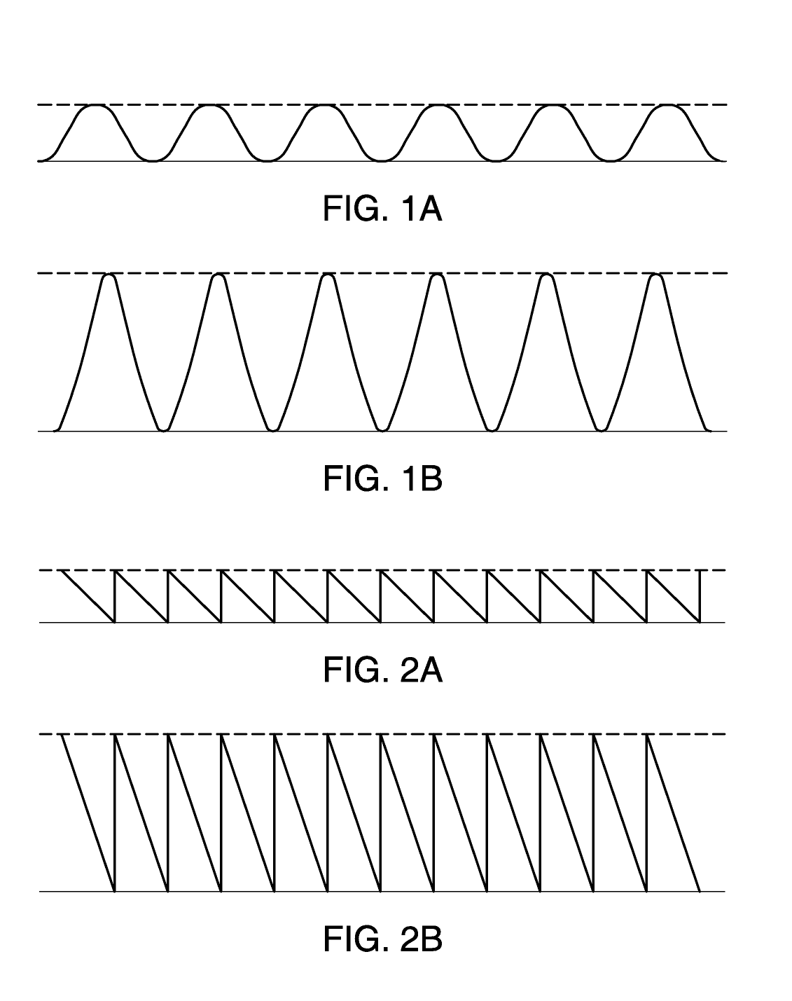

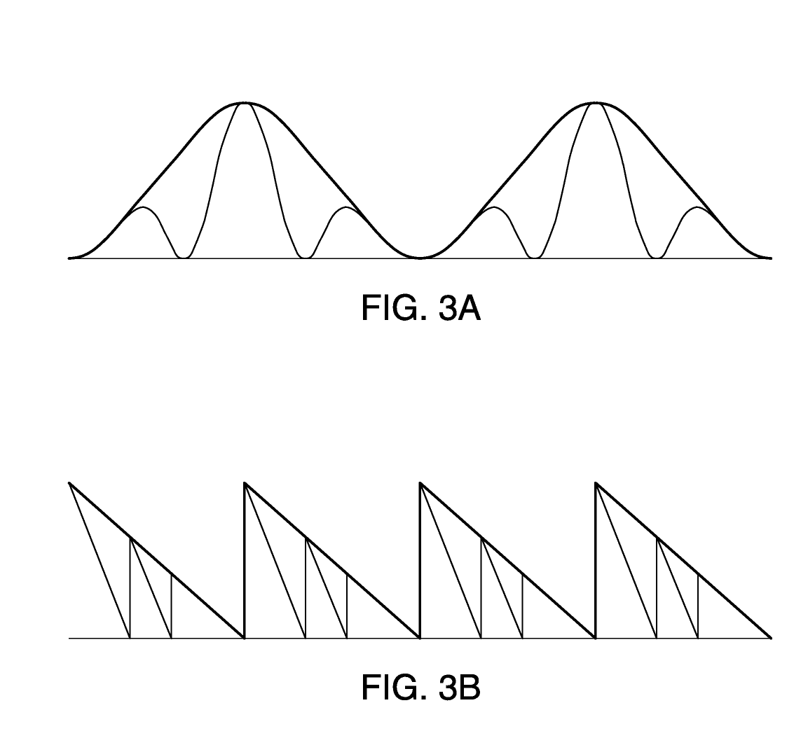

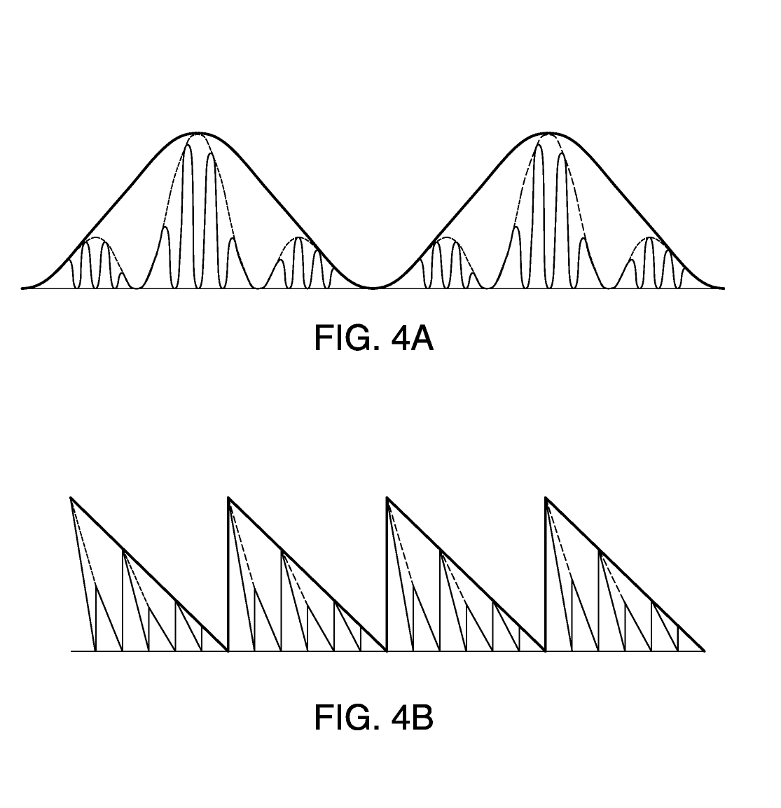

The Stage 1 inductors 46 reside within the air core of the Stage 2 inductors 47. The Stage 2 windings comprise an insulated non-magnetic conductor, such as copper. The Stage 2 inductors 47 receive an alternate version of the input analog audio signal of Stage 1 53. The Stage 2 input signal 53 is a version of the Stage 1 input waveform 50 that has been expanded in terms of amplitude and/or frequency. In the case of frequency expansion, the Stage 2 input 53 would have a lower frequency as to which the Stage 1 input waveform 50 would be an nth harmonic (where n could be 2, 3, 4 . . .). For example, the Stage 2 input could have the form of the wave envelope shown as the dark line of FIG. 3A corresponding to a Stage 1 input in the form depicted in FIG. 1A. In this example, the Stage 1 input is the third harmonic of the Stage 2 input, and the amplitude of the Stage 2 input is three times that of the Stage 1 input.

To generate the Stage 2 analog input signal 53, the original digital input audio signal 49 is processed to a lower harmonic frequency and amplified by a digital signal processor 57 and then converted to analog format by a second stage digital-to-analog signal processor 58.

The flow of the input signal through Stage 2 53 is symmetrical “push-pull”, so that there is a positive “push” signal at one end 53 and at the other end a negative “pull” signal 54 that is 180° phase-shifted so as to be the “reflection” of the “push signal”. The use of “push-pull” input in Stage 2 53 serves to eliminate harmonic distortion. In their function, the Stage 2 inductors 47 are somewhat analogous to the “primary” coils of a magnetic amplifier, but they also function as part of the cores of the inductors of Stage 3 48.

The Stage 2 inductors 47 reside within the air core of the Stage 3 inductors 48. Alternately, the windings of the Stage 3 inductors 48 can be wound around the same core as the Stage 2 inductors 47, with the Stage 3 windings either over the Stage 2 windings or with inductive bifilar inter-winding of the two stages. Like the Stage 2 windings, the Stage 3 windings comprise an insulated non-magnetic conductor, such as copper. An output signal 55, which is a recursively modulated version of the Stage 1 and 2 inputs 50 53, is induced in the Stage 3 inductors 48 by the magnetic flux generated by the Stage 2 signal 53. In this regard, Stages 1, 2 and 3 together function somewhat similarly to a magnetic amplifier circuit. Due to the presence of ferromagnetic material in the Stage 1 windings, Stage 1 46, in the absence of an input signal, affords a path of lower magnetic reluctance for the magnetic flux generated by Stage 2 47. Consequently, when the amplitude of the Stage 1 input signal 50 is low, most of the Stage 2 magnetic flux will couple into the Stage 1 coils 46, and very little of the Stage 2 flux will couple into the Stage 3 coils 48. On the other hand, when the amplitude of the Stage 1 input 50 is high, the Stage 1 coils 46 become magnetically saturated, thereby increasing their magnetic reluctance and causing more of the Stage 2 magnetic flux 47 to couple into the Stage 3 coils 48. Therefore, the magnetic flux coupled into Stage 3 from Stage 2 fluctuates in accordance with the Stage 1 analog input signal 50, and so does the signal induced in Stage 3 55 by that magnetic flux.

One major difference between the present invention and a conventional magnetic amplifier circuit, however, is that, in a conventional mag-amp circuit, the waveform of the “secondary” signal—in this case the signal induced in Stage 3 55—is determined solely by the waveform of the “control” signal—in this case the Stage 1 signal 50. This is because the wave envelope provided by the “primary” signal (Stage 2 here) is, in the conventional circuit, unmodulated. But, in the present invention, the “primary” signal of Stage 2 provides a wave envelope 53 that is modulated by a lower-harmonic, higher amplitude version of the “control” signal of Stage 1 50. Consequently, the waveform of the magnetic flux that couples into Stage 3 consists of harmonic fluctuations from the Stage 1 signal 50 within the wave envelope established by the Stage 2 signal 53. The effect of this first-order recursive modulation of the input signal is to induce in Stage 3 the type of self-similar signal response 55 we see (in simplified form) in FIGS. 3A and 3B.

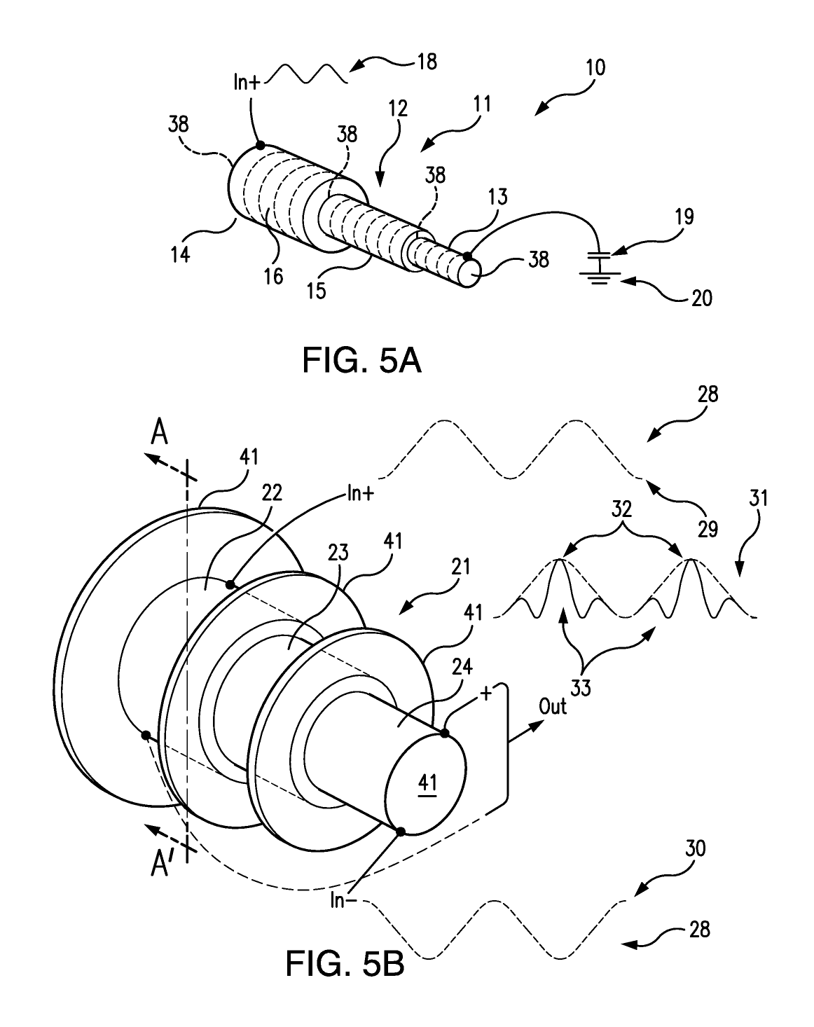

In the preferred embodiment of the present invention 10, the Stage 1 inductor coils 11 are wound around a three-tiered air-cored telescoping mandrel 12, as depicted in FIG. 5A. Since inductance in proportional to the cross-sectional area of the inductor core, the telescoping core structure provides a range of signal frequency responses, with the lower inductance top tier 13 being more responsive to higher frequencies, while the higher inductance base tier 14 responds better at lower frequencies, and the middle tier 15 accommodates mid-range frequencies.

The inductor windings 16 of the Stage 1 coils 11 preferably comprise composite strips of aluminum and nickel. Being a paramagnetic material, aluminum has a linear B-H curve which tends to attenuate the non-linearity of the B-H curve of nickel near the saturation point and thereby prevent high-end and low-end cutoffs. Optionally, this attenuating effect can be enhanced by inserting paramagnetic disks 38, preferably aluminum disks, at both ends of each of the tiers 13 14 15 of the Stage 1 coils 11.

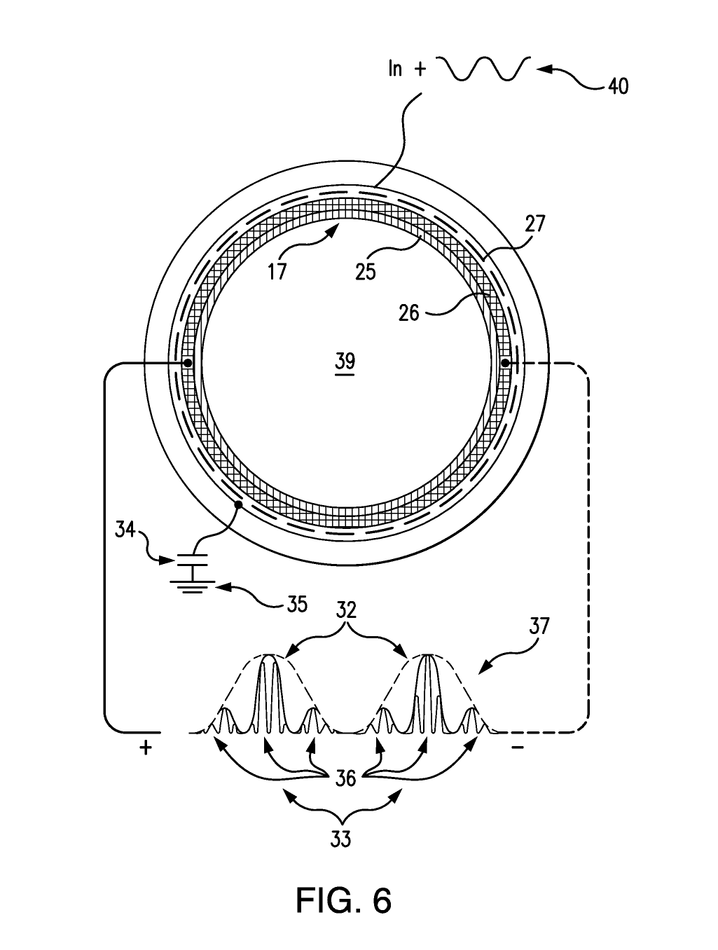

Since Stage 1 11 resides within the air core 39 of the Stage 2 inductor coils 17 (FIG. 6), the aluminum-nickel windings 16 of the Stage 1 coils 11 act as a high permeability core element that draws magnetic flux from the Stage 2 coils 17 in the absence of a strong input signal in Stage 1. As shown in FIG. 5A, a first analog audio input signal 18 passes through the Stage 1 inductor coils 11 and through a capacitor 19 to ground 20.

In this exemplary preferred embodiment, the Stage 2 and 3 inductor coils are wound over one another around a common core array comprising another three-tiered telescoping mandrel 21, as shown in FIG. 5B. The core 39 (FIG. 6) of the Stage 2 mandrel 21 is large enough to accommodate the Stage 1 mandrel 12 within it. Comprising a base tier 22, middle tier 23, and top tier 24, the Stage 2 mandrel 21, like its Stage 1 counterpart 12, affords a range of inductances and corresponding frequency responses. The end cross-sectional view of the Stage 2 mandrel 21 in FIG. 6 depicts the three layers comprising the innermost Stage 2 windings 25 overlain by the Stage 3 windings 26. Optionally, another recursive level can be added in the form of encompassing Stage 4 windings 27. The Stage 2 and Stage 3 windings 25 26 comprise insulated copper wire.

Referring again to FIG. 5B, the Stage 2 inductors carry a second analog audio input signal 28, which is a lower frequency amplified version of the Stage 1 first input signal 18, with the first input signal 18 being a nth harmonic (n=2, 3, 4 . . .) of the second input signal 28. The second input signal 28 traverses the Stage 2 winding 25 in “push-pull” format, with a positive component 29 and a 180° phase-shifted negative component 30.

As described above, the Stage 2 coils 25 generate a magnetic flux which variably couples with the Stage 3 coils 26 in accordance with the fluctuations of the Stage 1 input signal 18. This fluctuating magnetic flux induces a first-order recursive signal 31 in the Stage 3 coils 26. The first-order recursive signal 31 comprises an overall wave envelope 32, formed by the second input signal 28, and first-order harmonic waveforms 33, formed by the first input signal 18, within the overall envelope 32.

Referring to FIG. 6, the optional Stage 4 coils 27, like those of Stage 1 11, preferably comprise composite strips of aluminum and nickel. The third analog audio input signal 40, identical to the Stage 1 input signal 18, but phase-shifted by 180°, passes through the Stage 4 inductor coils 27 and through a capacitor 34 to ground 35. Due to its highly permeable materials, the Stage 4 inductors 27 variably draw magnetic flux from the Stage 2 coils 25, though to a much lesser degree than do the Stage 1 inductors 16. This variable magnetic coupling of Stages 2 and 4, fluctuating with the strength of the third input signal 40, superimposes a layer of second-order harmonic waveforms 36 within the “envelope” of the first order harmonic waveforms 33, thereby generating a second-order recursive output signal 37.

Optionally, to attenuate non-linearities in the magnetic coupling between the Stage 4 inductors 27 and the Stage 2 inductors, end plates 41 can be provided at both ends of each of the tiers 22 23 24 of the Stage 2 mandrel 21, as shown in FIG. 5B. The front and back surfaces of each of the end plates 41 are coated with a thin layer of paramagnetic material, preferably aluminum.

Although the preferred embodiments of the present invention have been disclosed for illustrative purposes, those skilled in the art will appreciate that many additions, modifications and substitutions are possible, without departing from the scope and spirit of the present invention as defined by the accompanying claims.

What is claimed is:

1. A device for recursively modulating an analog audio input signal, comprising a multiple levels of nested inductors, wherein each inductor comprises coils of an electrical conductor wound around a cylindrical core, and wherein the multiple levels of nested inductors include one or more innermost inductors, one or more outermost inductors, and one or more successively higher levels of inductors between the innermost inductors and the outermost inductors, and wherein each successively higher level of inductors in positioned within the core(s) of the next successively higher level of inductors, and wherein all of the multiple levels of nested inductors are positioned within the core(s) of the outermost inductors.

2. A method of recursively modulating an analog audio first input signal, comprising the steps of:
(a) providing one or more primary inductors, one or more secondary inductors, and one or more control inductors;
(b) generating an analog audio second input signal from the first input signal, such that the first input signal is a harmonic of second input signal;
(c) passing the first input signal through the control inductors;
(d) passing the second input signal through the primary inductors;
(e) using variations in the magnetic permeability of the control inductors caused by the first input signal to correspondingly vary the magnetic coupling between the primary inductors and the secondary inductors; and
(f) inducing an analog recursive signal in the secondary inductors, wherein the recursive signal comprises a first harmonic element having a waveform determined by the waveform of the first input signal and having a variable amplitude determined by an amplitude envelope in the form of the second input signals.

3. A method of recursively modulating an analog audio first input signal, comprising the steps of:
(a) providing one or more primary inductors, one or more secondary inductors, and one or more first-order control inductors, and one or more second-order control inductors;
(b) generating an analog audio second input signal from the first input signal, such that the first input signal is a harmonic of second input signal;
(c) passing the first input signal through the first-order control inductors and the second-order control inductors;
(d) passing the second input signal through the primary inductors;
(e) using variations in the magnetic permeability of the first-order control inductors caused by the first input signal to correspondingly vary the magnetic coupling between the primary inductors and the secondary inductors;
(f) inducing an analog first-order recursive signal in the secondary inductors, wherein the first-order recursive signal comprises a first harmonic element having a waveform determined by the waveform of the first input signal and having a variable amplitude determined by an amplitude envelope in the form of the second input signal;
(g) using variations in the magnetic permeability of the second-order control inductors caused by the first input signal to influence the magnetic coupling between the primary inductors and the secondary inductors; and
(h) inducing an analog second-order recursive output signal in the secondary inductors, wherein the second-order recursive output signal comprises the first harmonic element and a second harmonic element having a waveform determined by the waveform of the first input signal and having a variable amplitude determined by an amplitude envelope in the form of the first harmonic element.
